(19) United States
(12) Patent Application Publication
(10) Pub. No.: US 2006/0222967 A1
(43) Pub. Date: Oct. 5, 2006

(54) Reticle, method for manufacturing magnetic disk medium using reticle, and magnetic disk medium

(75) Inventors: Takeshi Okino, Yokohama-Shi (JP); Seiji Morita, Yokohama-Shi (JP); Masatoshi Sakurai, Tokyo (JP); Shinobu Sugimura, Yokohama-Shi (JP)

Correspondence Address: NIXON & VANDERHYE, PC, 901 NORTH GLEBE ROAD, 11TH FLOOR, ARLINGTON, VA, 22203, US

(73) Assignee: KABUSHIKI KAISHA TOSHIBA,, Tokyo (JP)

(21) Appl. No.: 11/372,342

(22) Filed: Mar. 10, 2006

(30) Foreign Application Priority Data
Mar. 28, 2005 (JP) 2005-92759

(51) Int. Cl. G03C 5/00; G21K 5/00; G03F 1/00

(52) U.S. Cl. 430/5; 378/35; 430/311; 430/312

(57) ABSTRACT

It is made possible to obtain a reticle which has a high strength even it is formed in a doughnut shape, a method for manufacturing a magnetic disk medium using the reticle, and a magnetic disk medium using the same. The magnetic disk medium has a toroidal pattern pattern. A pattern positioned at a central portion of the toroidal pattern is provided with an opening portion and a non-opening portion.

### CROSS-REFERENCE TO RELATED APPLICATION

This application is based upon and claims the benefit of priority from prior Japanese Patent Application No. 2005-92759 filed on Mar. 28, 2005 in Japan, the entire contents of which are incorporated herein by reference.

### BACKGROUND OF THE INVENTION

1. Field of the Invention

The present invention relates to a magnetic disk medium of a discrete type, a reticle for projection exposure for manufacturing an original disk serving as a mold for a stamper used during manufacture of the magnetic disk medium, and a method for manufacturing a magnetic disk medium using the reticle.

2. Related Art

In a technical trend to density growth of a hard disk (hereinafter, also called “magnetic disk”), a medium structure of the so-called discrete type where magnetic portion regions generating magnetic signals are partitioned by non-magnetic regions has been proposed. For example, JP-A-2004-110896 describes a recording/reproducing system of a medium of a discrete type having a data zone and a servo zone. However, there is not a description about how to manufacture the medium of a discrete type in JP-A-2004-110896.

On the other hand, U.S. Pat. No. 5,772,905 describes a technique for transferring a mold pattern of 200 nm or less on a film, which is so-called “nano-imprint lithography”. JP-A-2003-157520 describes a technique for transferring a magnetic disk pattern of a discrete type utilizing imprinting. JP-A-2003-157520 also describes an example where a medium pattern is formed using a stamper obtained from an original disk manufactured utilizing an electron beam lithography, but it does not include a description about an approach of the electron beam lithography itself.

In general, a magnetic disk apparatus is provided inside thereof with a toroidal disk-like magnetic disc, a head slider including a magnetic head, a head suspension assembly supporting the head slider, a voice coil motor (VCM), and a circuit board.

The magnetic disk where ring-like concentric tracks are sectioned and each track has sectors sectioned for each predetermined angle is attached to a spindle motor to be rotated so that various digital data elements are recorded and reproduced by the head. Therefore, user data tracks are arranged in a circumferential direction, while servo marks for positional control are arranged so as to cross the respective tracks. The servo mark includes regions such as a preamble portion, an address portion, and a burst portion. Besides, the servo mark can include a gap portion.

It is desirable that both the user disk track region and the servo region are simultaneously formed in a stamper original disk for manufacturing a magnetic disk of a discrete type utilizing an imprint system. When one of both regions is added after the other is formed, it becomes difficult to position the one to the other, which results in requirement for a complicated step(s).

In manufacture of an original disk, its pattern can be formed by exposing photosensitive resin using a mercury lamp or actinic rays such as ultraviolet rays, electron beams, or X-rays. Especially, it is preferable that an approach of performing direct lithography using an electron beam synchronized with a signal source is utilized for forming a magnetic disk pattern which requires drawing concentric circles, because the electron beam can be deflected. For example, using an electron beam lithographing apparatus of a stage continuous moving system having a movement mechanism and a rotation mechanism based upon one direction moving shaft, a pattern can be formed by irradiating a spot beam from one point on the moving shaft to photosensitive resin on a substratee placed on a stage to perform electron beam exposure.

However, unless the electron beam is not applied with external force, a spiral pattern is drawn. In order to get a concentric circle deflection is applied on an electron beam while changing intensity of the electron beam for each rotation in the exposure step. On the other hand, lines in a radial direction can be drawn in a continuous manner by emitting a beam or stopping emission of a beam only when each line reaches a predetermined angle. Specifically, when a medium where the servo region and the data region have been arranged is obtained, a desired exposure pattern including connected lines can be obtained by applying such deflection as to increase a deflection amount linearly according to rotation of the stage for each rotation and make the deflection amount zero at a return time of the stage to its original position after one rotation. When positive type resist is used, an exposed portion constitutes a recessed portion after developed, and it becomes a projection portion after a stamper is manufactured by electroforming. The servo portion of the medium can be formed in an arc shape corresponding to a locus of an arm of the head portion instead of a constitution that the servo portion extends straightly in a radial direction.

Now, since the movement mechanism and the rotation mechanism based upon the one direction moving shaft include some feeding precision error or rotational jitter in fact during exposure, collapsing of a pattern occurs. As an approach for solving this problem, a reduced projection exposure can be used.

According to the reduced projection exposure, even if there is unevenness in a pattern, the size of the unevenness is reduced due to reduced projection. The reduced projection is performed by irradiating such a beam as an electron beam on a mask (hereinafter, called “reticle”) with a pattern opening to be projected, reducing a beam which has passed through the opening, and irradiating the reduced beam on a substrate to be exposed.

The electron beam reduced projection technique mainly includes SCALPEL (Scattering with Angular Limited in Projection Electron Lithography) system described in S. D. Berger et al., Applied Physics Letters, 57, 153 (1990) and PREVAIL (Projection Exposure with Variable Axis Immersion Lens) system disclosed in Japanese Patent No. 2829942. In these systems, a mask of a stencil type (hereinafter, also called “stencil mask”) and a mask of a membrane type (hereinafter, also called “membrane mask”) are used as masks.

When the stencil mask is used, an electron beam passes an opening of the stencil mask to scatter at a non-opening portion of the mask. The membrane mask is constituted of a membrane portion made from light element which allows easy transmission of an electron beam and a heavy metal pattern layer which is formed on the membrane to scatter an electron beam. A film such as silicon film or a silicon nitride film is used as the membrane portion, while chromium (Cr) or tungsten (W) is used as material for the pattern layer.

Since the opening of the stencil mask through which a beam passes is a through-hole, low scattering or chromatic aberration as caused in the membrane mask does not occurs. In view of a structure of the stencil mask, however, a mask having a pattern such as a toroidal pattern having an opening at the center thereof can not be produced due to opening for defining an outer periphery of the doughnut shape. Therefore, an approach of using a complementary mask to conduct plural exposures is applied to such an issue. However, such an approach includes a problem of positioning or throughput. A cantilever pattern may become weak in mechanical strength, which causes damage easily.

On the other hand, since the membrane mask is provided with the membrane portion, even such a pattern as a toroidal pattern can be formed. However, the membrane mask includes such a tendency that a toroidal pattern or a cantilever pattern is weak like the stencil mask. In the membrane mask, such a drawback arises that slight low scattering occurs at a time of transmission of an electron beam through the membrane, which results in occurrence of chromatic aberration.

Especially, in the stencil mask, a problem of strength arises in such a constitution that a large non-opening pattern is supported using a fine pattern wire. On the contrary, when there is a large opening pattern, a pattern portioned around the opening pattern can not obtain a sufficient support, which easily causes a problem similar to the problem occurring in the cantilever pattern. In the membrane mask, the problem of strength is relatively reduced, but such a problem arises that strain depending on a pattern easily occurs due to a difference in stress between the heavy metal and the light element thin film.

Here, since such a disk as a hard disk medium, a compact disk, and a DVD (digital versatile disk) is formed in a doughnut shape, a mask used to manufacture an original disk therefor must have a toroidal pattern necessarily. When a projection mask used to manufacture an original disk for such a doughnut type is prepared, a central portion of a doughnut pattern is generally formed in a non-opening pattern or an opening pattern, but such a mask includes such a problem that strength becomes weak, as described above.

### SUMMARY OF THE INVENTION

The present invention has been made in view of these circumstances, and an object thereof is to provide a reticle which has a high strength even it is formed in a doughnut shape, a method for manufacturing a magnetic disk medium using the reticle, and a magnetic disk medium using the same.

A reticle according to a first aspect of the present invention includes a toroidal pattern, a pattern of a central portion of the toroidal pattern including an opening portion and a non-opening portion.

The pattern of the central portion can be formed in a fan shape, in a network defined with triangular holes, a network defined with tetragonal holes, or a network defined with regular hexagonal holes, or it is formed by a combination of these holes.

One of an alignment mark and an identification mark can be provided within the pattern of the central portion.

The reticle can be of a membrane type.

The reticle can be of a stencil type.

An opening area ratio of the central portion of the toroidal pattern can be an opening area ratio of the toroidal pattern or more.

An opening area ratio of the central portion of the toroidal pattern can be in a range of 50% or more to 98% or less.

The reticle can be used for electron beam reduced projection exposure.

A method for manufacturing a magnetic disk medium according to a second aspect of the present invention, which performs manufacturing of a magnetic disk medium using imprint process, includes: forming a master disk having a resist pattern formed on a surface of the master disk in order to manufacture a stamper used in the imprint process by conducting electron beam projection exposure using the above-described reticle.

A magnetic disk medium according to a third aspect of the present invention is manufactured according to the manufacturing method above-described.

### BRIEF DESCRIPTION OF THE DRAWINGS

FIG. 1 is a plan view showing a pattern of a reticle according to a first embodiment of the present invention;

FIG. 2 is a plan view showing a pattern of a reticle according to a first modification of the first embodiment;

FIG. 3 is a plan view showing a pattern of a reticle according to a second modification of the first embodiment;

FIG. 4 is a plan view showing a pattern of a reticle according to a third modification of the first embodiment;

FIG. 5 is a plan view showing a pattern of a reticle according to a fourth modification of the first embodiment;

FIG. 6 is a plan view showing a pattern of a reticle according to a fifth modification of the first embodiment;

FIG. 7 is a plan view showing a pattern of a reticle according to a sixth modification of the first embodiment;

FIG. 8 is a plan view showing a pattern of a reticle according to a seventh modification of the first embodiment;

FIG. 9 is a view showing a configuration of a projection exposure apparatus where the reticle according to the first embodiment is used;

FIG. 10 is a view showing a configuration of a projection exposure apparatus where the reticle according to the first embodiment is used;

FIG. 11 is a plan view of a specific example of a magnetic disk medium;

FIG. 12 is a plan view showing a pattern of a conventional reticle having a toroidal pattern;

FIG. 13 is a plan view showing a pattern of a conventional reticle having a toroidal pattern;

FIG. 14 is a plan view showing a pattern of a conventional reticle having a toroidal pattern;

FIGS. 15A to 15G are sectional views showing a method for manufacturing a magnetic disk medium of a discrete type according to a second embodiment of the present invention;

FIGS. 16A to 16F are sectional views showing the method for manufacturing a magnetic disk medium of a discrete type according to the second embodiment of the present invention;

FIGS. 17A to 17C are sectional views showing a method for manufacturing a reticle of a membrane type according to Example 1 of the present invention;

FIGS. 18A to 18C are sectional views of the method for manufacturing the reticle of a membrane type according to Example 1 of the present invention;

FIGS. 19A to 19D are sectional views showing a method for manufacturing a reticle of a stencil type according to Example 2 of the present invention;

FIGS. 20A to 20C are sectional views showing the method for manufacturing the reticle of a stencil type according to Example 2 of the present invention; and

FIGS. 21A to 21D are sectional views showing a method for manufacturing a magnetic disk medium of a discrete type according to Example 3 of the present invention.

### DETAILED DESCRIPTION OF THE INVENTION

Embodiments of the present invention will be explained below in detail with reference to the drawings.

### First Embodiment

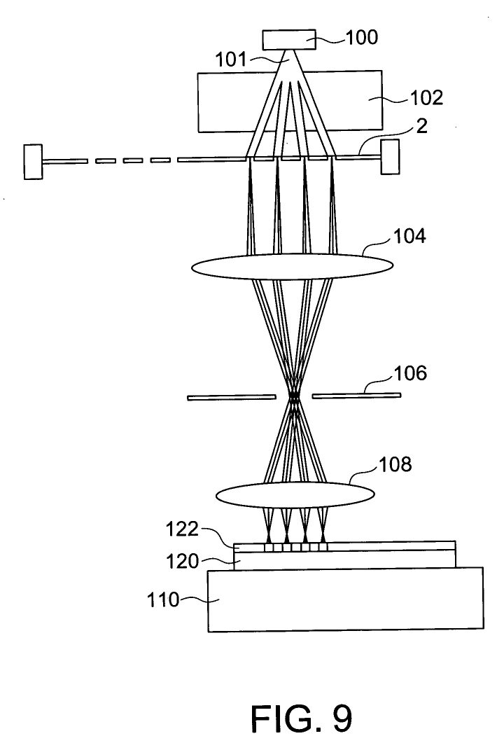

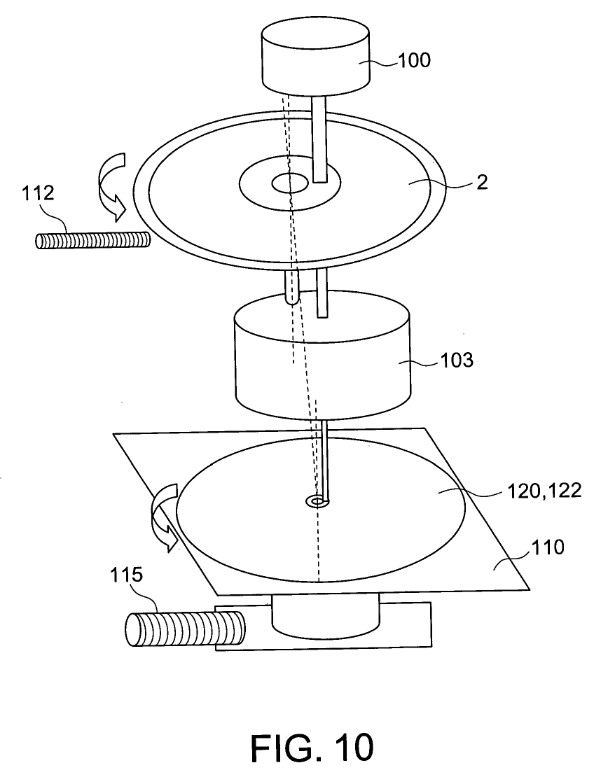

Reticles of a first embodiment and a modification thereof according to the present invention will be explained. A reticle of the embodiment is used in a projection exposure apparatus. As shown in FIG. 9, the projection exposure apparatus is constituted such that electron beams 101 emitted from an electron beam source 100 are deflected within a certain range by a deflector 102 so that only beams which have passed through a reticle 2 according to the embodiment passes through a plurality of projection lenses 104 and an aperture 106 to be irradiated on resist 122 made from photosensitive resin and formed on a substrate 120 placed on a stage 110. As shown in FIG. 10, the rectile 2 and the stage 110 on which the substrate 120 is placed are driven by driving systems 112 and 115, respectively, so that the electron beams 101 are irradiated evenly according to rotational movements of the reticle 2 and the stage and a pattern obtained through the reticle 2 is projected on the resist 122 for exposure.

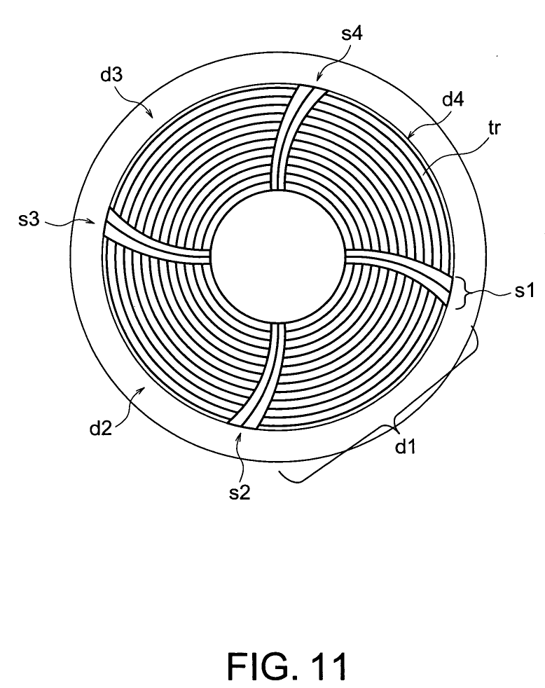

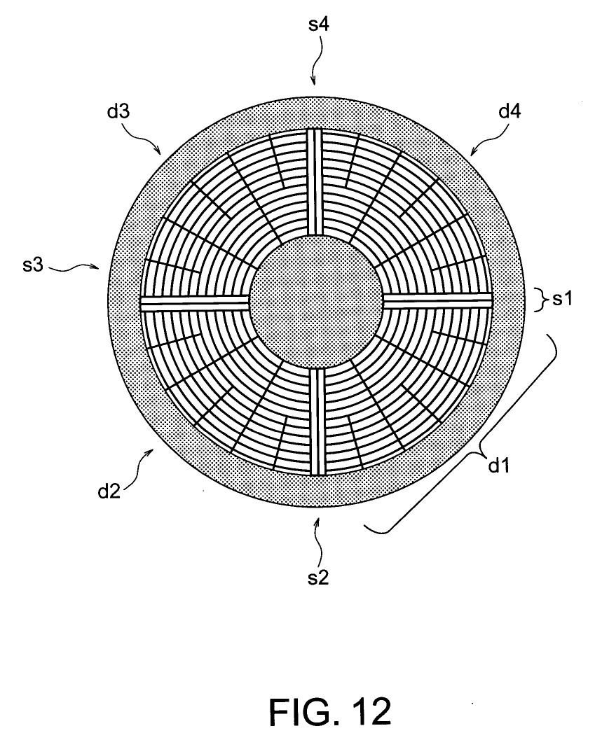

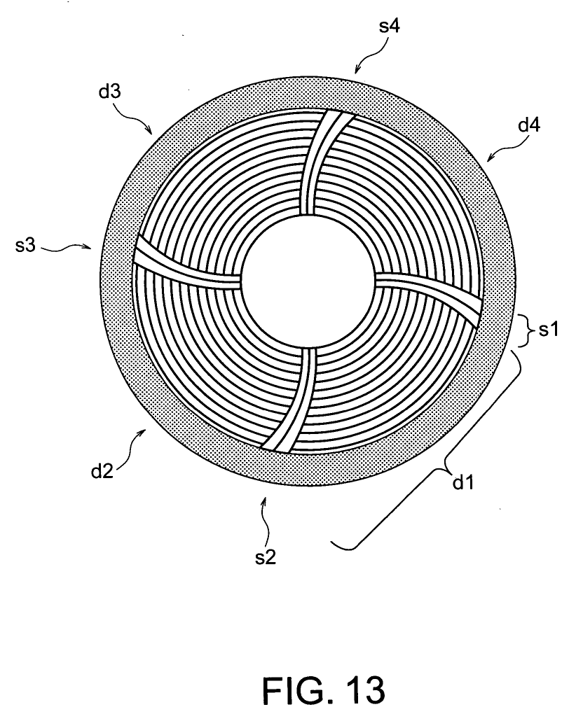

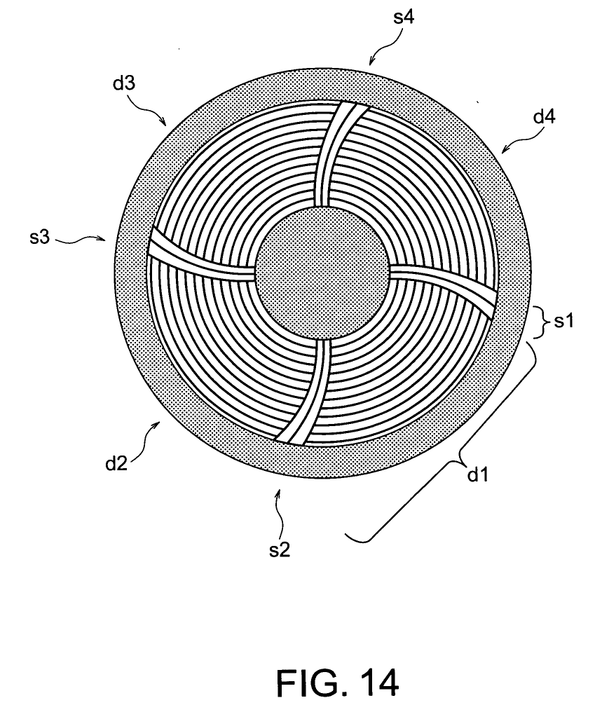

As shown in FIG. 11, a magnetic disk medium provided with four data regions d1 to d4 and servo regions s1 to s4 positioned between the data regions d1 and d4, between the data regions d1 and d2, between the data regions d2 and d3, and between the data region d3 and d4 will be explained as an example. FIG. 11 is a plan view of a specific example of the magnetic disk medium. Each data region has a plurality of tracks tr. Incidentally, the servo regions s1 to s4 are each formed in an arc shape extending along a locus of an arm in FIG. 11. A conventional reticle having a toroidal pattern for manufacturing such a magnetic disk medium is generally provided with a hole formed at the central portion thereof or a plate (or closed) portion formed thereat, as shown in FIGS. 12 to 14. For example, FIGS. 12 and 14 show toroidal patterns of reticles having a closed central portion, while FIG. 13 shows a toroidal pattern of a reticle having a hole at a central portion thereof. Incidentally, the servo regions s1 to s4 extend straightly in FIG. 12.

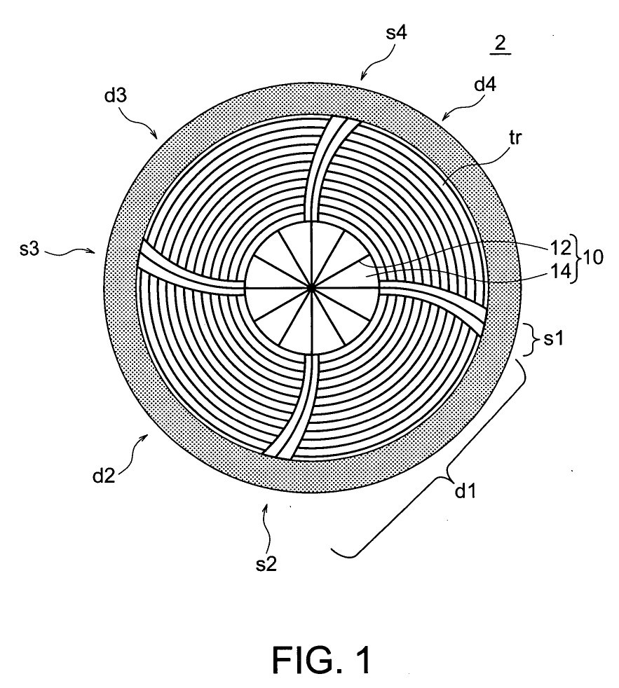

On the other hand, a toroidal pattern of the reticle 2 according to the embodiment is constituted such that a central portion 10 has wires (non-opening portions) 12 extending in a radial direction. That is, the embodiment is constituted such that the central portion 10 includes the non-opening portions 12 and an opening portion 14, which is different from the conventional toroidal patterns. In FIG. 1, radial wires correspond to the non-opening portion, and the opening portion is constituted of a combination of a plurality of fan-shaped openings which are symmetrical about a point.

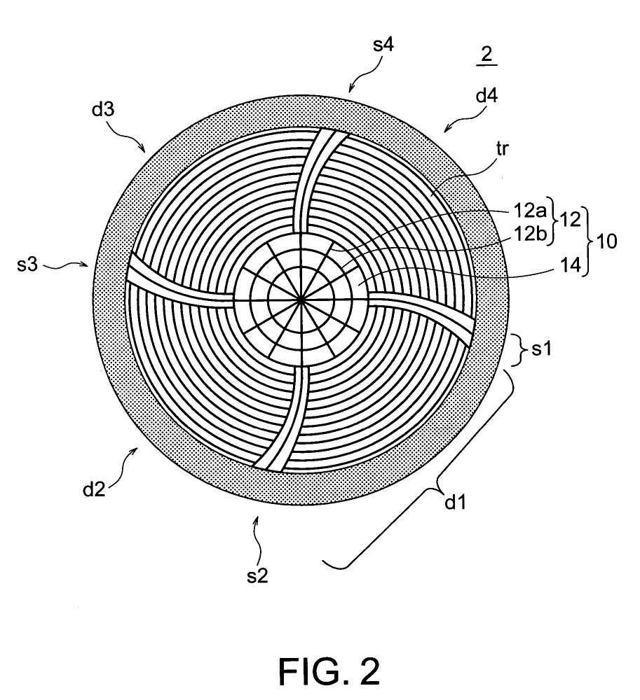

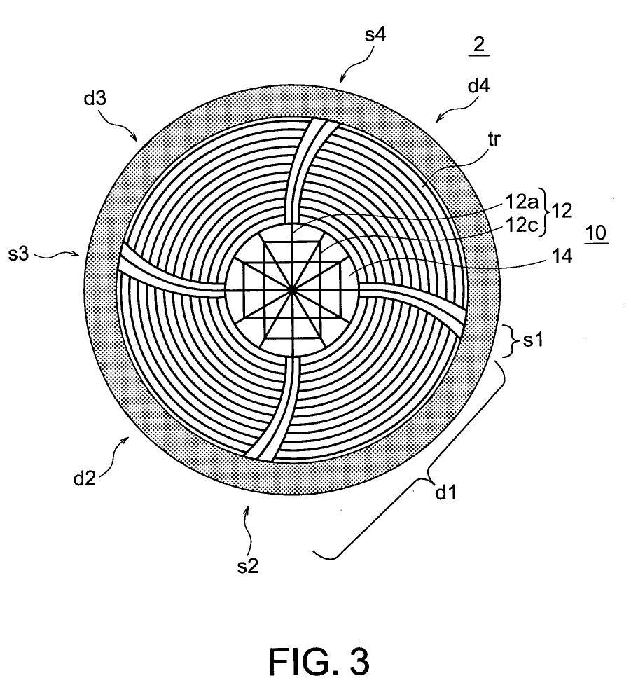

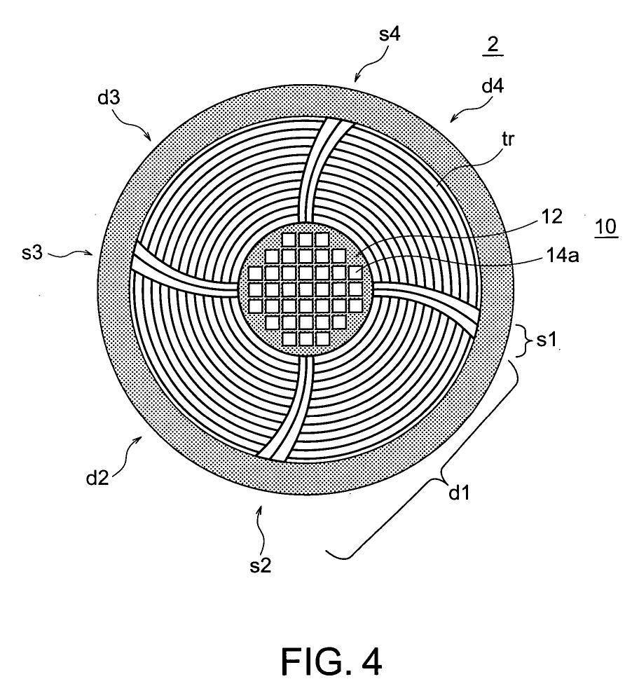

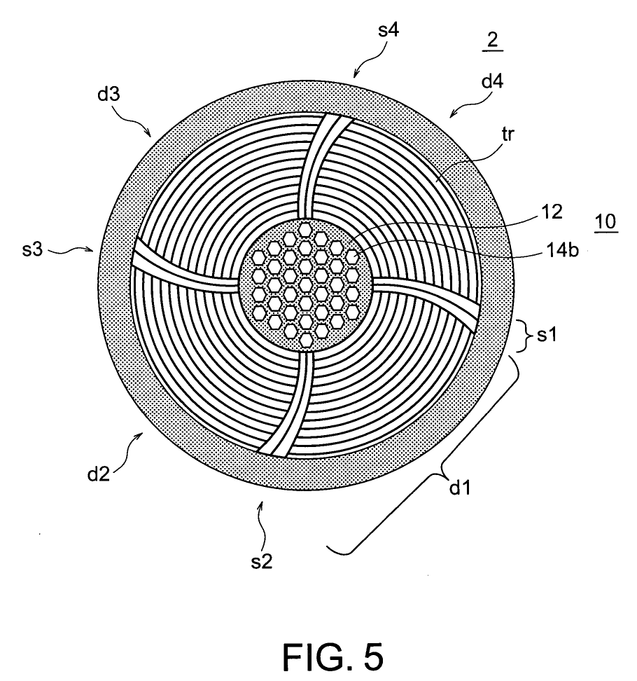

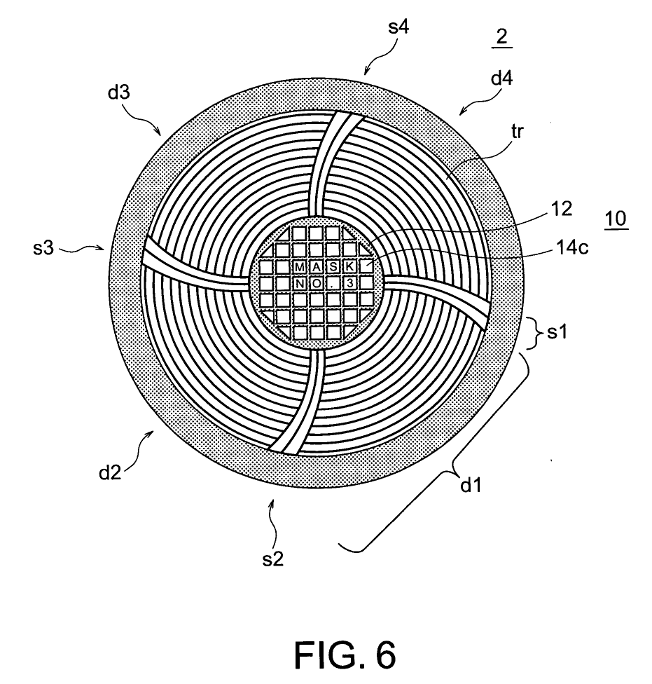

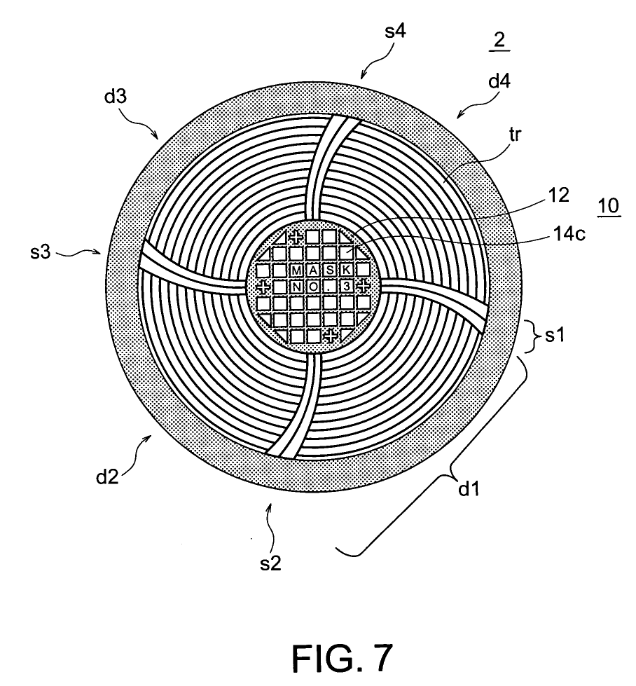

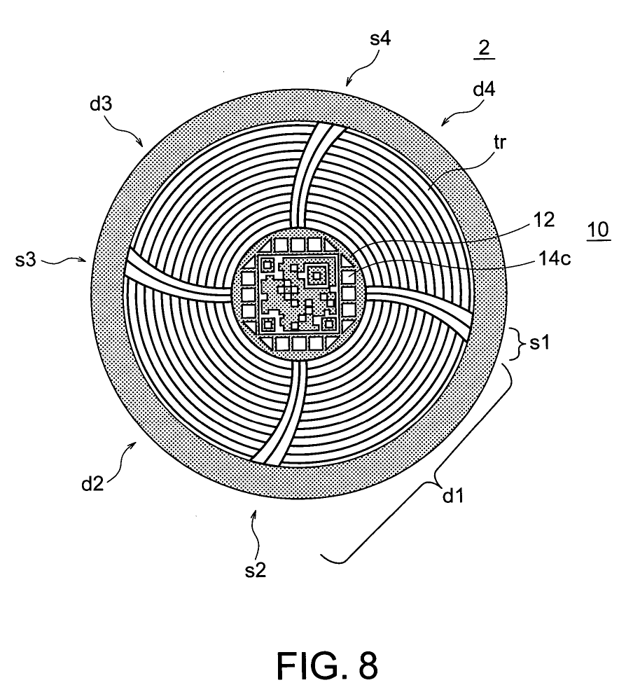

If a pattern positioned in a central portion of a toroidal pattern is provided with the non-opening portions 12 and the opening portion 14 in this manner, as shown in FIG. 2, the non-opening portion 12 is not required to be constituted of radial wires 12a and circular or annular wires 12b. As shown in FIG. 3, the non-opening portion 12 may be constituted of radial wires 12a and wires forming sides 12c of a tetragon (or square) or a triangle. Further, as shown in FIG. 4, the opening portion may be formed in a pattern having a plurality of tetragonal holes 14a arranged. As shown in FIG. 5, the opening portion may be formed in a pattern having regularly hexagonal holes 14b arranged in array. As shown in FIG. 6, the opening portion may be formed in a pattern arranged with tetragonal holes and triangular holes 14c arranged and formed with characters. As shown in FIG. 7, the opening portion may be formed in a pattern arranged with tetragonal holes and triangular holes 14c and formed with alignment marks. As shown in FIG. 8, the opening portion may be formed in a pattern arranged with tetragonal holes and triangular holes 14c and formed with an identification mark, for example, a barcode figure. Accordingly, the pattern positioned at the central portion of the toroidal pattern may be formed in a fan shape, in a network defined with triangular holes, a network defined with tetragonal holes, or a network defined with regular hexagonal holes, or it may be formed by a combination of these holes.

At all events, the reticle 2 is required to only have the non-opening portion 12 and the opening portion 14 in the pattern positioned at the central portion of the toroidal pattern, where it is preferable that the pattern at the central portion is formed to be symmetrical about a point.

An opening area ratio on the central portion of the toroidal pattern (=an area of an opening portion on the central portion/an area of the central portion) should be set to be at least an opening area ratio of the toroidal pattern (=an area of the opening portion of the whole pattern/an area of the whole pattern), and it is preferably set in a range of 50% or more to 98% or less. When the opening area ratio on the central portion of the toroidal pattern exceeds 98%, the toroidal pattern can not be supported sufficiently, so that the strength of the reticle 2 can not be made sufficiently high, as compared with that of a reticle with a cantilever pattern. On the other hand, when the opening area ratio on the central portion of the toroidal pattern is set to be less than 50%, especially, it is set to be at most the opening area ratio of the toroidal pattern, such a setting differs little from the non-opening state where it is difficult for the surrounding toroidal pattern portion about the central portion of the toroidal pattern to support the central portion, so that a possibility that a reticle with high strength can be obtained is reduced.

Such a pattern as shown in FIGS. 1 to 8 does not cause falling-off and it does not include a large cantilever portion, so that a reticle 2 with high strength can be obtained. Here, the reticle 2 may be of the stencil type or of the membrane type. However, when each of the patterns shown in FIGS. 6 to 8 is applied to the stencil type, falling-off is caused, so that these patterns should be applied to the membrane type.

Though a method for manufacturing a reticle is not limited to a specific one, it is preferable in view of saving the need for the positioning step that a sub-field commonly used is not included.

In the embodiment, a case that the number of sectors is four is shown for ease of explanation, but the number may exceed a hundred. A non-opening portion (not shown) between tracks in a radial direction is not required to be continuous and straight. However, it is preferable for eliminating unevenness of strength that the non-opening portion is disposed at intervals of a fixed range to some extent.

In FIGS. 1 to 8, outer frame portions of the respective rectiles are each shown to have a circular shape, but they are not formed in the circular shape necessarily. Each outer frame portion may be formed in a square shape. Incidentally, it is preferable for maintaining evenness of strength that the outer frame portion has a shape approximating to a circle concentric with the pattern or an outer frame of the reticle has a width relative to the pattern of the reticle to such an extent that evenness of strength can be obtained.

In the embodiment, the size of the reticle, the size of the magnetic disk medium, and the size ratio therebetween are not limited to specific ones. However, when the size of the reticle is excessively large, such a problem as lack of strength or large-sizing of the apparatus itself occurs. When the reduction ratio is reduced, and the sizes of the reticle and the magnetic disk medium are not so changed, it becomes difficult to achieve reduction of unevenness of a pattern which is the advantage obtained using the reduced projection exposure. Therefore, for example, it is preferable that the size of the magnetic disk medium is 2 inches or less, the size of the reticle is 8 inches or less, and the reduction magnification is in a range of about ½ to ⅕.

The pattern of the reticle and the pattern of the magnetic disc medium are not required to be analogous to each other necessarily, and the pattern of the reticle may be a pattern making an allowance for optical compensation from exposure.

As explained above, according to the embodiment and the modification thereof, a reticle having high strength despite toroidal pattern can be obtained.

### Second Embodiment

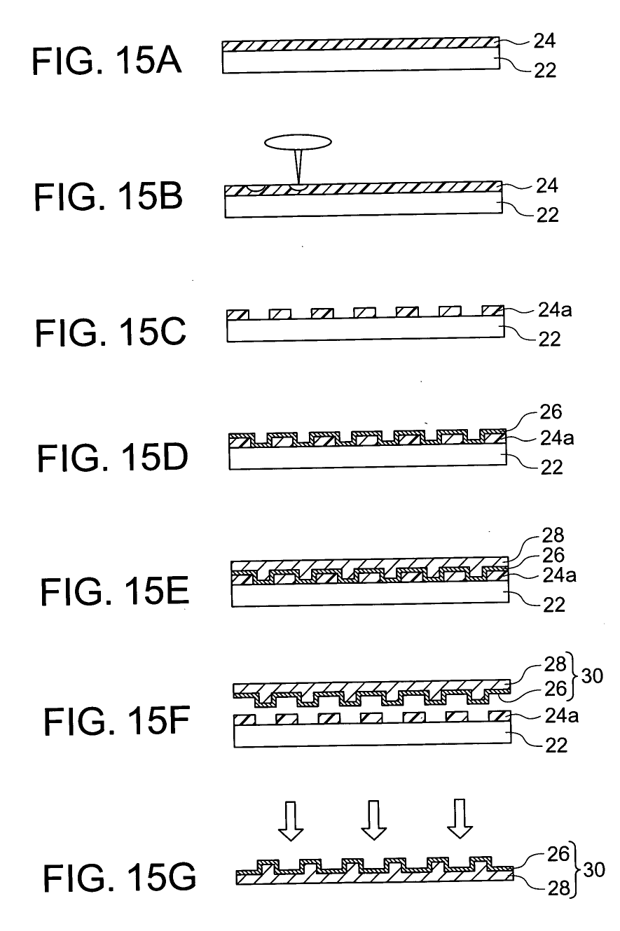

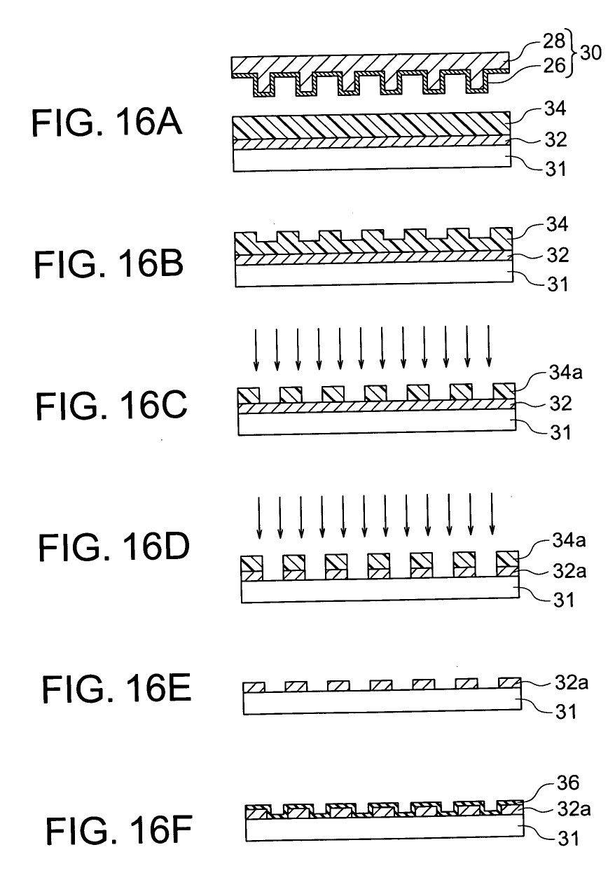

Next, a method for manufacturing a magnetic disk medium of a discrete type according to a second embodiment of the present invention will be explained With reference to FIGS. 15A to 16F. In the method for manufacturing a magnetic disk medium according to the embodiment, the reticle explained regarding the first embodiment is used in an exposing step.

Photosensitive resin (hereinafter, called “resist”) 24 is applied on a substrate 22 (see FIG. 15A). The resist 24 may be of a positive type or of a negative type, or it may be of a chemical amplification type or a non-chemical amplification type, but it is preferable in view of stability of sensitivity to an electron beam or excellent resolution that positive type resist of a non-chemical amplification type is used. Besides, material mainly containing PMMA (polymethylmethacrylate) or novolac resin can be used as the resist. After application of the resist 24, pre-baking is performed, and the substrate 22 is then placed in a vacuum chamber of an electron lithographing apparatus, where reduced projection exposure to the substrate is performed (see FIG. 15B). The reticle according to the first embodiment can be used in the reduced projection exposure, for example. An electron beam which has passed through the reticle and lenses such as a condenser lens is shown in FIG. 15B. In this embodiment, positive type resist is used as the resist. The resist 24 is exposed in this manner.

Thereafter, the resist 24 is developed using developing solution, and a resist pattern 24a is formed so that a resist original disk is manufactured (see FIG. 15C). Incidentally, before the resist 24 is developed, a post-baking step may be conducted.

Next, an electrically conductive thin film 26 is formed on the resist pattern 24a of the resist original disk utilizing such process as Ni sputtering process (see FIG. 15D). At that time, a film thickness of the resist pattern 24a is set such that shapes of recesses on the resist pattern 24a can be maintained sufficiently. Thereafter, a Ni film 28 is sufficiently buried in the recesses of the resist pattern 24a by electroforming such that a thickness thereof is formed to have a predetermined thickness (see FIG. 15E).

Next, the Ni film 28 is peeled off from the resist original disk constituted of the resist 24a and the substrate 22, so that a stamper 30 constituted of the electrically conductive film 26 and the Ni film is formed (see FIG. 15F). Thereafter, oxygen RIE (reactive ion etching) or the like is performed in order to remove the remaining resist on the stamper 30 (see FIG. 15G).

Next, as shown in FIG. 16A, a magnetic layer 32 functioning as a recording layer is formed on a substrate 31, and a magnetic disc medium substrate is prepared by applying resist 34 on the magnetic layer 32. Imprinting on the resist 34 applied on the magnetic disk medium substrate is performed by using the above-described stamper 30 (see FIG. 16A), and a pattern on the stamper 30 is transferred on the resist 34 (see FIG. 16B).

Next, the resist 34 is etched using the pattern transferred on the resist 34 as a mask so that a resist pattern 34a is formed (see FIG. 16C). Thereafter, ion milling is performed on the magnetic layer 32 using the resist pattern 34a as a mask (see FIG. 16D). Subsequently, the resist pattern 34a is removed by conducting dry etching or using chemical solution, so that a discrete magnetic layers 32a are formed (see FIG. 16E).

Next, a protective film 36 is formed on a whole surface of the magnetic disk medium substrate 31 with the discrete magnetic layer 32a, so that a magnetic disk medium is completed (see FIG. 16F). Incidentally, a step for burying non-magnetic material in recessed portions such as grooves can be performed additionally.

It is preferable in view of an approach applied to the manufacturing method according to the embodiment that the magnetic disk medium manufactured by the manufacturing method is formed in a disk-shape or in a doughnut shape, but a size of the magnetic disk medium is not limited to a specific one. However, it is preferable that the size is 3.5 inches or less such that a lithographing time utilizing an electron beam does not become excessive. It is preferable that the size is 2.5 inches or less such that a pressing force applied at an imprinting time does not become excessive. When reduced exposure projection is used, it is more preferable, especially, in view of mask productivity that the size is 1.0 inch or less, for example, 0.85 inch. In the magnetic disk medium, one side face or both side faces can be used as a recording face or recording faces.

A shape of the substrate on which a pattern is formed using the manufacturing method of the embodiment is not limited to a specific one, but it is preferably disk-shaped, for example, a silicon wafer disk can be used. Here, the disk may have a notch or an oriented flat. As another substrate, a glass substrate, an Al series alloy substrate, a ceramic substrate, a carbon substrate, a compound semiconductor substrate can be used. The glass substrate can be made from amorphous glass or crystal glass. As the amorphous glass, soda lime glass, aluminosilicate glass, or the like can be used. As the crystal glass, there is lithium series crystal glass. As the ceramic substrate, a sintered body mainly containing aluminum oxide, aluminum nitride, silicon nitride, or the like, or material obtained by fiber-reinforcing the sintered body, or the like can be used. As the compound semiconductor substrate, there are GaAs, AlGaAs, and the like.

The magnetic disk medium where ring-like concentric tacks are sectioned and each track has sectors sectioned for each predetermined angle is attached to a spindle motor to be rotated so that various digital data elements are recorded and reproduced by the head. Therefore, user data tracks are arranged in a circumferential direction, while servo marks for positional control are arranged so as to cross the respective tracks. The servo mark includes regions such as a preamble portion, an address portion which is written the information of tracks or sectors numbers, and a burst portion due to the relative position detection for the tracks. Besides, the servo mark can include a gap portion.

Examples of the present invention will be explained below.

### EXAMPLE 1

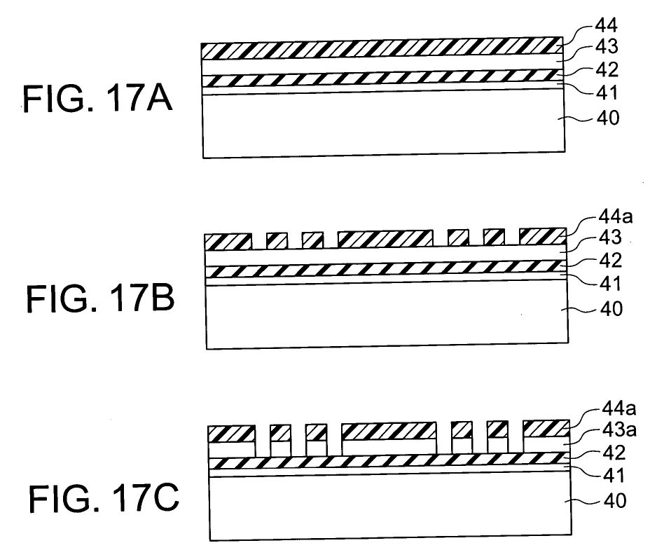

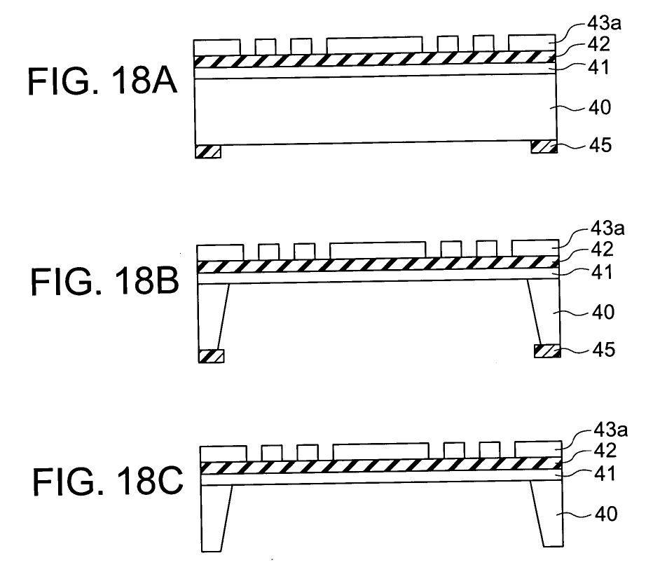

A method for manufacturing a reticle according to Example 1 of the present invention will be explained with reference to FIGS. 17A to 18C. The reticle (mask) manufactured according to the manufacturing method of Example 1 was of a membrane type.

A membrane film 41 with a thickness of 0.1 μm made from diamond was formed on a silicon substrate 40 by plasma CVD (chemical vapor deposition) process, and a silicon oxide film 42 serving as a stopper at an etching time was formed thereon (see FIG. 17A). Subsequently, a membrane film 43 with a thickness of 1.2 μm made from diamond was formed by plasma CVD process, and solution obtained by diluting resist to 1.5 times using anisole solution and filtrating the resist solution using a 0.21 μm membrane filter was spin-coated on the membrane film 43 and was pre-baked at a temperature of 200° C. for 3 minutes, so that a resist layer 44 with a thickness of 0.2 μm was formed (see FIG. 17A).

Next, the substrate thus obtained was conveyed to a predetermined position inside an electron beam lithographing apparatus (not shown) using a conveying system (not shown) of the apparatus, where the substrate was exposed under vacuum with a pattern at a central portion of a toroidal pattern shown in FIG. 7 by electron beams within an x-y electron beam lithographing apparatus. Next, a pattern (a toroidal portion in FIG. 7) expanded up to an outer diameter of 3.4 inches which was four times a hard disk pattern to be obtained was similarly exposed under vacuum by electron beams within a γ-θ type electron beam lithographing apparatus. After exposure, a resist pattern 44a was formed by dipping the silicon substrate in developing solution for 90 seconds to conduct developing, thereafter dipping the developed silicon substrate in rinsing liquid for 90 seconds to perform rinsing, and further drying the rinsed substrate using air blowing (see FIG. 17B).

Thereafter, the membrane film 43 was dry-etched by oxygen gas plasma using the resist pattern 44a as a mask until the silicon oxide film 42 was exposed, so that a membrane film pattern 43a was formed (see FIG. 17C). Subsequently, the resist pattern 44a was removed.

Next, resist was applied on a back face of the silicon substrate 40 and a resist pattern 45 was formed according to lithographic technique (see FIG. 18A). Thereafter, the silicon substrate 40 was etched using KOH (potassium hydroxide) until the membrane 41 was exposed (see FIG. 18B), and a membrane mask (reticle) was then obtained by removing the resist pattern 45 (see FIG. 18C).

Next, Example of the method for manufacturing a magnetic disk medium using the membrane mask (reticle) manufactured according to the manufacturing method of the Example will be explained with reference to FIGS. 15A to 16G.

As shown in FIG. 15A, resist 24 obtained by diluting resist to 2 times using anisole solution and filtrating the resist solution using a 0.2 μm membrane filter was spin-coated on a silicon substrate 22. Just thereafter, the silicon substrate 22 was pre-baked for 3 minutes so that a resist with a thickness of 0.1 μm was obtained.

A pattern reduced to an outer diameter of 0.85 inch corresponding to ¼ of a mask size was transferred on the resist by exposure via the above-described membrane mask using a reducing projection electron beam exposing apparatus. After exposure, a resist original disk with a resist pattern 24a was obtained by dipping the silicon substrate in developing solution for 90 seconds to develop the same, thereafter dipping the developed substrate in rinsing liquid for 90 seconds to rinse the same, and drying the substrate using air blowing (see FIG. 15C).

Next, as shown in FIG. 15D, an electrically conductive thin film 26 was formed on the resist original disk according to sputtering process. Here, pure nickel was used as target, and sputtering was conducted for 40 seconds by applying DC power of 400 W within a chamber vacuumed to 8×10⁻³ Pa and then introduced with argon gas to be adjusted to 1 Pa, so that the electrically conductive film 26 with a thickness of 30 nm was obtained.

Thereafter, the resist original disk attached with the electrically conductive film 26 was electroformed for 90 minutes so that an electroformed film 28 was formed (see FIG. 15E). Conditions for the electroforming were as follows:

Nickel sulfamate: 600 g/L

Boric acid: 40 g/L

Interfacial active agent (sodium lauryl sulfate): 0.15 g/L

Temperature of liquid: 55° C.

PH: 4.0

Current density: 20 A/dm²

A thickness of the electroformed film 28 obtained at that time was 300 μm.

Thereafter, a stamper 30 with the electrically conductive film 26, the electroformed film 28, and the resist residue was obtained from peeling off the electroformed film from the resist original disk (see FIG. 15F). Subsequently, the resist residue was removed by oxygen plasma ashing process (see FIG. 15G). In the oxygen plasma ashing process, plasma ashing was conducted with power of 100 W for 20 minutes in a chamber in which oxygen gas was introduced at a rate of 100 ml/min and which was adjusted to vacuum of 4 Pa. Thereby, a father stamper 30 with the electrically conductive film 26 and the electroformed film 28 was obtained. Next, an imprint stamper was obtained by removing unnecessary portions from the stamper though punching-out.

After the stamper 30 was cleaned for 15 minutes using asetone, the stamper was dipped in solution obtained by diluting fluoroalkyl silane [CF₃(CF₂)₇CH₂CH₂Si(OMe)₃](TSL8233 manufactured by GE TOSHIBA SILICON CORP.) to 5% solution using ethanol for 30 minutes and solution adhered on the stamper was blown off by a blower, the stamper 30 was annealed at 120° C. for 1 hour.

On the other hand, as shown in FIG. 16A, a magnetic recording layer 32 for vertical recording was formed on a 0.85-inch toroidal glass substrate 31 by sputtering process, and novolac series resin was spin-coated on the magnetic recording layer 32 at a rotational speed of 3800 rpm, so that a resist film 34 was formed. Thereafter, while the center of four cross-shaped alignment marks (not shown) on the above-described stamper 30 was being optically detected, positioning of a substrate 31 to be processed was conducted so that the stamper and the substrate were superimposed with each other. Thereafter, the pattern on the stamper 30 was transferred on the resist film 34 by conducting pressing for 1 minute with pressure of 2000 bar (see FIG. 16B). UV irradiation on the resist film 34 transferred with the pattern was performed for 5 minutes, the substrate was heated at a temperature of 160° C. for 30 minutes.

A resist pattern 34a was formed by using an ICP (induction coupling plasma) etching apparatus to perform oxygen RIE on the resist film 34 on the substrate imprinted in the above manner under etching pressure of 2 mTorr (see FIG. 16C). Subsequently, the magnetic recording film 32 was etched using Ar ion milling and utilizing the resist pattern 34a as a mask so that a discrete magnetic recording layer 32a was formed (see FIGS. 16D and 16E). After the magnetic recording layer 32a was formed, oxygen RIE was conducted with a power of 400 W and a pressure of 1 Torr in order to peel off the resist pattern 34a serving as the etching mask.

After the magnetic recording layer 32a was formed, a DLC (diamond like carbon) 36 with a thickness of 3 nm was formed as a protective film according to a CVD (chemical vapor deposition) process (see FIG. 16F). Further, lubricant was applied to the substrate 30 so as to form a film with a thickness of 1 nm thereon using dip process, so that a magnetic disk medium could be obtained. When the magnetic disk medium obtained in the Example was incorporated in a magnetic recording apparatus and signal evaluation was performed, an excellent magnetic signal could be obtained. A detection value obtained from a position error signal was small.

### EXAMPLE 2

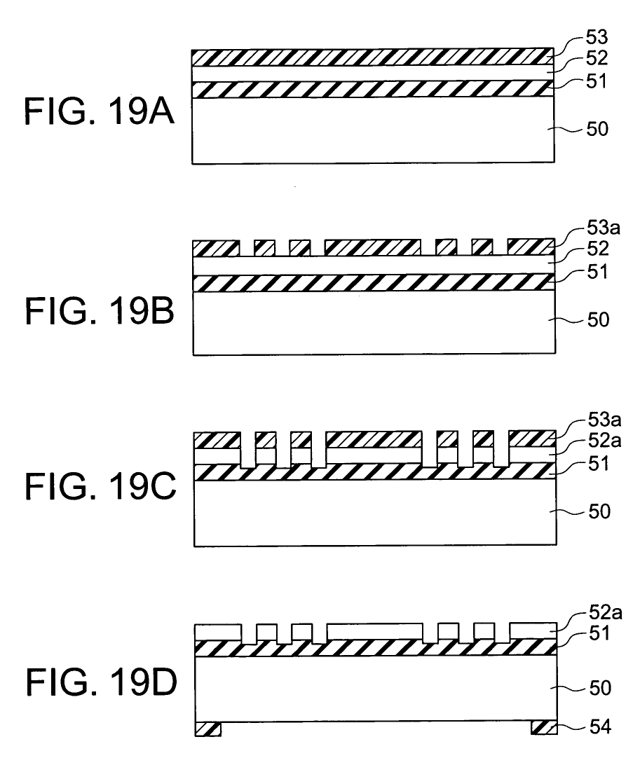

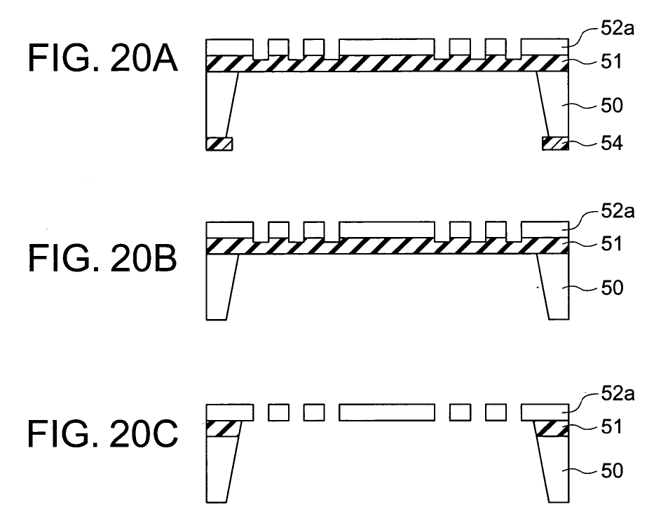

Next, a method for manufacturing a reticle according to Example 2 of the present invention will be explained with reference to FIGS. 19A to FIG. 20C. A reticle (mask) manufactured according to the manufacturing method of the Example was of a stencil type.

As shown in FIG. 19A, first, a silicon oxide film 51 functioning as a stopper at an etching time was formed on a silicon substrate 50, and an SOI substrate obtained by forming an SOI (silicon on insulator) layer 52 on the silicon oxide film 51 was prepared. Solution obtained by diluting resist to 1.5 times using anisole solution and filtrating the resist solution using a 0.2 μm membrane filter was spin-coated on the SOI layer 52 and was pre-baked at a temperature of 200° C. for 3 minutes so that a resist layer with a thickness of 0.2 μm was formed (see FIG. 19B).

Next, the substrate thus obtained was conveyed to a predetermined position inside an electron beam lithographing apparatus (not shown) using a conveying system (not shown) of the apparatus, where a pattern shown in FIG. 2 was exposed on the resist layer 53 under vacuum by electron beams within a γ-θ electron beam lithographing apparatus. After exposure, a resist pattern 53a was formed by dipping the SOI substrate in developing solution for 90 seconds to conduct developing, thereafter dipping the developed SOI substrate in rinsing liquid for 90 seconds to perform rinsing, and further drying the rinsed substrate using air blowing (see FIG. 19B).

Subsequently, anisotripic etching was applied to the SOI layer 52 using the resist pattern 53a as a mask until the silicon oxide film 51 was exposed, so that a patterned SOI layer 52a was obtained (see FIG. 19C). Thereafter, the resist pattern 53a was removed.

Next, resist was applied on a back face of the silicon substrate 50 and a resist pattern 54 was formed according to lithographic technique (see FIG. 19D). Thereafter, the silicon substrate 50 was etched utilizing the resist pattern 54 as a mask and using KOH (potassium hydroxide) until the silicon oxide film 51 was exposed (see FIG. 20A). Subsequently, the resist pattern 54 was removed (see FIG. 20B). Further, the silicon oxide film 51 except for the silicon oxide film positioned between the silicon substrate 50 and the patterned SOI layer 52a was removed using fluorinated acid, so that a stencil mask was obtained (see FIG. 20C).

A magnetic disk medium was manufactured using the stencil mask according to steps similar to those in example 1. When the magnetic disk medium obtained in this manner was incorporated in a magnetic recording apparatus and signal evaluation was performed, an excellent magnetic signal could be obtained.

Each of the magnetic disk media explained in Examples 1 and 2 was a magnetic substance-patterned medium, namely, it is obtained by working a magnetic substance (a magnetic recording layer) formed on a substrate, but it may be a substrate-patterned medium. A method for manufacturing the substrate-patterned discrete track media (magnetic disk medium) will be explained as Example 3.

### EXAMPLE 3

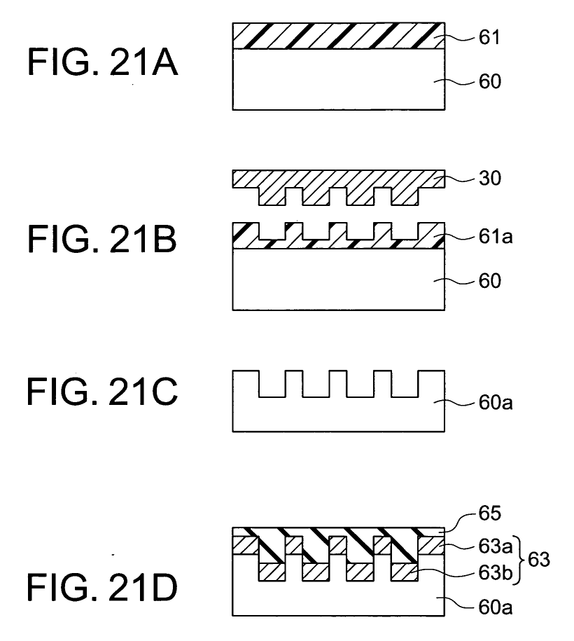

Next, a method for manufacturing a magnetic recording medium will be explained with reference to FIGS. 21A to 21D. A magnetic recording medium (media) manufactured according to the manufacturing method of the Example was a substrate-patterned discrete track media.

First, an imprint stamper was manufactured according to an approach similar to the approach shown in FIGS. 15A to 15G.

An undulated or corrugated substrate was manufactured using imprint lithographing process, as described below. As shown in FIG. 21A, resist 61 for imprinting was applied on a substrate 60. Subsequently, as shown in FIG. 21B, a stamper 30 was caused to be opposed to the resist 61 on the substrate 60, and the stamper 30 was pressed on the resist 61 by applying force on the stamper 30, so that a projection pattern on a surface of the stamper 30 was transferred on a surface of the resist 61. Thereafter, the stamper was removed. Thereby, a resist pattern 61a having a corrugated pattern on the resist 61 could be obtained (see FIG. 21B).

Next, a substrate 60a with the corrugated pattern was obtained by etching the substrate 60 using the resist pattern 61a as a mask. Thereafter, the resist pattern 61a was removed (see FIG. 21C).

Subsequently, as shown in FIG. 21D, a magnetic film made from material suitable for vertical recording was formed on the substrate 61a. At that time, magnetic films formed on projection portions of the substrate 60a constituted projection portion magnetic portions 63a, while magnetic films formed on recessed portions of the substrate 60a constituted recessed portion magnetic portions 63b. Incidentally, it is preferable that the magnetic film 63 is constituted of a stacked film of a soft magnetic base layer and a ferromagnetic recording layer. Further, a magnetic recording medium was manufactured by providing a protective film 65 made from carbon on the magnetic film 63 and further applying lubricant thereon.

A magnetic substance portion and a non-magnetic substance portion of the magnetic film-patterned discrete track media described in FIG. 16F correspond to the projection portion magnetic portion 63a and the recessed portion magnetic portion 63b in the Example, respectively. The corresponding functions in the both the magnetic recording media in magnetic recording apparatuses are the same.

As described above, according to each of the embodiments of the present invention, a reticle which has a high strength even it is formed in a doughnut shape, a method for manufacturing a magnetic disk medium using the reticle, and a magnetic disk medium using the same can be obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

What is claimed is:

1. A reticle comprising a toroidal pattern, a pattern of a central portion of the toroidal pattern including an opening portion and a non-opening portion.

2. A reticle according to claim 1, wherein the pattern of the central portion is formed in a fan shape, in a network defined with triangular holes, a network defined with tetragonal holes, or a network defined with regular hexagonal holes, or it is formed by a combination of these holes.

3. A reticle according to claim 1 wherein one of an alignment mark and an identification mark is provided within the pattern of the central portion.

4. A reticle according to claim 1, wherein the reticle is of a membrane type.

5. A reticle according to claim 1, wherein the retice is of a stencil type.

6. A reticle according to claim 1 wherein an opening area ratio of the opening portion of the toroidal pattern is an opening area ratio of the toroidal pattern or more.

7. A reticle according to claim 1, wherein an opening area ratio of the central portion of the toroidal pattern is in a range of 50% or more to 98% or less.

8. A reticle according to claim 1, wherein the reticle is used for electron beam reduced projection exposure.

9. A reticle according to claim 1, wherein the pattern of the central portion is symmetrical about a point as a whole.

10. A reticle according to claim 9, wherein one of an alignment mark and an identification mark is provided within the pattern of the central portion.

11. A reticle according to claim 9, wherein the reticle is of a membrane type.

12. A reticle according to claim 9, wherein the reticle is of a stencil type.

13. A reticle according to claim 9, wherein an opening area ratio of the central portion of the toroidal pattern is an opening area ratio of the toroidal pattern or more.

14. A reticle according to claim 9, wherein an opening area ratio of the central portion of the toroidal pattern is in a range of 50% or more to 98% or less.

15. A reticle according to claim 9, wherein the reticle is used for electron beam reduced projection exposure.

16. A method for manufacturing a magnetic disk medium, which performs manufacturing of a magnetic disk medium using imprint process, including:
forming a master disk having a resist pattern formed on a surface of the master disk in order to manufacture a stamper used in the imprint process by conducting electron beam projection exposure using the reticle according to claim 1.

17. A method for manufacturing a magnetic disk medium according to claim 16, further comprising:
forming an electrically conductive film on the resist pattern of the master disk to allow transfer of a shape of a recess of the resist pattern on a surface of the electrically conductive film;
forming a metal film on the electrically conductive film to bury the metal film in a recess of the resist pattern transferred on the electrically conductive film; and
peeling off the master disk to form a stamper comprising the metal film and the electrically conductive film.

18. A method for manufacturing a magnetic disk medium according to claim 17, comprising:
forming a resist layer on a magnetic layer on a substrate having the magnetic layer formed on surface thereof;
performing imprinting on the resist layer using the stamper to transfer a pattern on the stamper on the resist layer;
performing patterning on the resist layer using the pattern transferred on the resist layer as a mask to form a resist pattern; and
patterning the magnetic layer using the resist pattern as a mask.

19. A method for manufacturing a magnetic disk medium according to claim 17, comprising:
forming a resist pattern on a substrate;
imprinting the resist layer using the stamper to transfer a pattern on the stamper on the resist layer;
performing patterning on the substrate using the pattern transferred on the resist layer; and
forming a magnetic film on the substrate.

20. A magnetic disk medium manufactured according to the manufacturing method according to claim 16.
